(19) United States
(12) Patent Application Publication
(10) Pub. No.: US 2016/0285284 A1
(43) Pub. Date: Sep. 29, 2016

(54) BATTERY MAINTENANCE SYSTEM

(71) Applicant: Midtronics, Inc., Willowbrook, IL (US)

(72) Inventors: Vijay Matlapudi, Woodridge, IL (US); Francisco X. Garcia, Aurora, IL (US)

(21) Appl. No.: 15/077,975

(22) Filed: Mar. 23, 2016

Related U.S. Application Data
(60) Provisional application No. 62/137,491, filed on Mar. 24, 2015.

(51) Int. Cl. H02J 7/00; G01R 31/36

(52) U.S. Cl. CPC H02J 7/0021; G01R 31/3658

(57) ABSTRACT

A battery maintenance system for performing maintenance on a string of storage batteries includes a plurality of battery monitors each of which is configured to electrically couple to a battery in the string of batteries and measure an electrical parameter of the string of batteries. A plurality of controllable electrical loads, each of which are configured to electrically couple to a battery within the string of batteries. The electric loads are controlled during charging of the string of batteries as a function of the parameters measured by the plurality of battery monitors.

### CROSS-REFERENCE TO RELATED APPLICATION

The present application is based on and claims the benefit of U.S. provisional patent application Ser. No. 62/137,491, filed Mar. 24, 2015, the content of which is hereby incorporated by reference in its entirety.

### BACKGROUND

The present invention relates to battery maintenance systems. More specifically, the present invention relates to charging and maintenance of strings of storage batteries.

Storage batteries are used to directly power or provide a backup power source for many types of installations. For example, storage batteries are used as a backup power source in telecommunications (for example cellular sites, computing facilities, water treatment facilities, power distribution facilities, etc.).

In such facilities, a large number of individual storage batteries are connected in an array referred to as a “string.” The string may have any number of series or parallel connected batteries to provide the desired storage capacity and voltage. The batteries may be charged by applying a constant voltage charger across the entire string. However, this may lead to inefficient charging and may even be a source of accelerated degradation for good batteries in the string.

Various examples of battery maintenance devices and related technology are shown and described in U.S. Pat. No. 3,873,911, issued Mar. 25, 1975, to Champlin; U.S. Pat. No. 3,909,708, issued Sep. 30, 1975, to Champlin; U.S. Pat. No. 4,816,768, issued Mar. 28, 1989, to Champlin; U.S. Pat. No. 4,825,170, issued Apr. 25, 1989, to Champlin; U.S. Pat. No. 4,881,038, issued Nov. 14, 1989, to Champlin; U.S. Pat. No. 4,912,416, issued Mar. 27, 1990, to Champlin; U.S. Pat. No. 5,140,269, issued Aug. 18, 1992, to Champlin; U.S. Pat. No. 5,343,380, issued Aug. 30, 1994; U.S. Pat. No. 5,572,136, issued Nov. 5, 1996; U.S. Pat. No. 5,574,355, issued Nov. 12, 1996; U.S. Pat. No. 5,583,416, issued Dec. 10, 1996; U.S. Pat. No. 5,585,728, issued Dec. 17, 1996; U.S. Pat. No. 5,589,757, issued Dec. 31, 1996; U.S. Pat. No. 5,592,093, issued Jan. 7, 1997; U.S. Pat. No. 5,598,098, issued Jan. 28, 1997; U.S. Pat. No. 5,656,920, issued Aug. 12, 1997; U.S. Pat. No. 5,757,192, issued May 26, 1998; U.S. Pat. No. 5,821,756, issued Oct. 13, 1998; U.S. Pat. No. 5,831,435, issued Nov. 3, 1998; U.S. Pat. No. 5,871,858, issued Feb. 16, 1999; U.S. Pat. No. 5,914,605, issued Jun. 22, 1999; U.S. Pat. No. 5,945,829, issued Aug. 31, 1999; U.S. Pat. No. 6,002,238, issued Dec. 14, 1999; U.S. Pat. No. 6,037,751, issued Mar. 14, 2000; U.S. Pat. No. 6,037,777, issued Mar. 14, 2000; U.S. Pat. No. 6,051,976, issued Apr. 18, 2000; U.S. Pat. No. 6,081,098, issued Jun. 27, 2000; U.S. Pat. No. 6,091,245, issued Jul. 18, 2000; U.S. Pat. No. 6,104,167, issued Aug. 15, 2000; U.S. Pat. No. 6,137,269, issued Oct. 24, 2000; U.S. Pat. No. 6,163,156, issued Dec. 19, 2000; U.S. Pat. No. 6,172,483, issued Jan. 9, 2001; U.S. Pat. No. 6,172,505, issued Jan. 9, 2001; U.S. Pat. No. 6,222,369, issued Apr. 24, 2001; U.S. Pat. No. 6,225,808, issued May 1, 2001; U.S. Pat. No. 6,249,124, issued Jun. 19, 2001; U.S. Pat. No. 6,259,254, issued Jul. 10, 2001; U.S. Pat. No. 6,262,563, issued Jul. 17, 2001; U.S. Pat. No. 6,294,896, issued Sep. 25, 2001; U.S. Pat. No. 6,294,897, issued Sep. 25, 2001; U.S. Pat. No. 6,304,087, issued Oct. 16, 2001; U.S. Pat. No. 6,310,481, issued Oct. 30, 2001; U.S. Pat. No. 6,313,607, issued Nov. 6, 2001; U.S. Pat. No. 6,313,608, issued Nov. 6, 2001; U.S. Pat. No. 6,316,914, issued Nov. 13, 2001; U.S. Pat. No. 6,323,650, issued Nov. 27, 2001; U.S. Pat. No. 6,329,793, issued Dec. 11, 2001; U.S. Pat. No. 6,331,762, issued Dec. 18, 2001; U.S. Pat. No. 6,332,113, issued Dec. 18, 2001; U.S. Pat. No. 6,351,102, issued Feb. 26, 2002; U.S. Pat. No. 6,359,441, issued Mar. 19, 2002; U.S. Pat. No. 6,363,303, issued Mar. 26, 2002; U.S. Pat. No. 6,377,031, issued Apr. 23, 2002; U.S. Pat. No. 6,392,414, issued May 21, 2002; U.S. Pat. No. 6,417,669, issued Jul. 9, 2002; U.S. Pat. No. 6,424,158, issued Jul. 23, 2002; U.S. Pat. No. 6,441,585, issued Aug. 17, 2002; U.S. Pat. No. 6,437,957, issued Aug. 20, 2002; U.S. Pat. No. 6,445,158, issued Sep. 3, 2002; U.S. Pat. No. 6,456,045; U.S. Pat. No. 6,466,025, issued Oct. 15, 2002; U.S. Pat. No. 6,465,908, issued Oct. 15, 2002; U.S. Pat. No. 6,466,026, issued Oct. 15, 2002; U.S. Pat. No. 6,469,511, issued Nov. 22, 2002; U.S. Pat. No. 6,495,990, issued Dec. 17, 2002; U.S. Pat. No. 6,497,209, issued Dec. 24, 2002; U.S. Pat. No. 6,507,196, issued Jan. 14, 2003; U.S. Pat. No. 6,534,993; issued Mar. 18, 2003; U.S. Pat. No. 6,544,078, issued Apr. 8, 2003; U.S. Pat. No. 6,556,019, issued Apr. 29, 2003; U.S. Pat. No. 6,566,883, issued May 20, 2003; U.S. Pat. No. 6,586,941, issued Jul. 1, 2003; U.S. Pat. No. 6,597,150, issued Jul. 22, 2003; U.S. Pat. No. 6,621,272, issued Sep. 16, 2003; U.S. Pat. No. 6,623,314, issued Sep. 23, 2003; U.S. Pat. No. 6,633,165, issued Oct. 14, 2003; U.S. Pat. No. 6,635,974, issued Oct. 21, 2003; U.S. Pat. No. 6,696,819, issued Feb. 24, 20144; U.S. Pat. No. 6,707,303, issued Mar. 16, 2004; U.S. Pat. No. 6,737,831, issued May 18, 2004; U.S. Pat. No. 6,744,149, issued Jun. 1, 2004; U.S. Pat. No. 6,759,849, issued Jul. 6, 2004; U.S. Pat. No. 6,781,382, issued Aug. 24, 2004; U.S. Pat. No. 6,788,025, filed Sep. 7, 2004; U.S. Pat. No. 6,795,782, issued Sep. 21, 2004; U.S. Pat. No. 6,805,090, filed Oct. 19, 2004; U.S. Pat. No. 6,806,716, filed Oct. 19, 2004; U.S. Pat. No. 6,850,037, filed Feb. 1, 2005; U.S. Pat. No. 6,850,037, issued Feb. 1, 2005; U.S. Pat. No. 6,871,151, issued Mar. 22, 2005; U.S. Pat. No. 6,885,195, issued Apr. 26, 2005; U.S. Pat. No. 6,888,468, issued May 3, 2005; U.S. Pat. No. 6,891,378, issued May 10, 2005; U.S. Pat. No. 6,906,522, issued Jun. 14, 2005; U.S. Pat. No. 6,906,523, issued Jun. 14, 2005; U.S. Pat. No. 6,909,287, issued Jun. 21, 2005; U.S. Pat. No. 6,914,413, issued Jul. 5, 2005; U.S. Pat. No. 6,913,483, issued Jul. 5, 2005; U.S. Pat. No. 6,930,485, issued Aug. 16, 2005; U.S. Pat. No. 6,933,727, issued Aug. 23, 200; U.S. Pat. No. 6,941,234, filed Sep. 6, 2005; U.S. Pat. No. 6,967,484, issued Nov. 22, 2005; U.S. Pat. No. 6,998,847, issued Feb. 14, 2006; U.S. Pat. No. 7,003,410, issued Feb. 21, 2006; U.S. Pat. No. 7,003,411, issued Feb. 21, 2006; U.S. Pat. No. 7,012,433, issued Mar. 14, 2006; U.S. Pat. No. 7,015,674, issued Mar. 21, 2006; U.S. Pat. No. 7,034,541, issued Apr. 25, 2006; U.S. Pat. No. 7,039,533, issued May 2, 2006; U.S. Pat. No. 7,058,525, issued Jun. 6, 2006; U.S. Pat. No. 7,081,755, issued Jul. 25, 2006; U.S. Pat. No. 7,106,070, issued Sep. 12, 2006; U.S. Pat. No. 7,116,109, issued Oct. 3, 2006; U.S. Pat. No. 7,119,686, issued Oct. 10, 2006; and U.S. Pat. No. 7,126,341, issued Oct. 24, 2006; U.S. Pat. No. 7,154,276, issued Dec. 26, 2006; U.S. Pat. No. 7,198,510, issued Apr. 3, 2007; U.S. Pat. No. 7,363,175, issued Apr. 22, 2008; U.S. Pat. No. 7,208,914, issued Apr. 24, 2007; U.S. Pat. No. 7,246,015, issued Jul. 17, 2007; U.S. Pat. No. 7,295,936, issued Nov. 13, 2007; U.S. Pat. No. 7,319,304, issued Jan. 15, 2008; U.S. Pat. No. 7,363,175, issued Apr. 22, 2008; U.S. Pat. No. 7,398,176, issued Jul. 8, 2008; U.S. Pat. No. 7,408,358, issued Aug. 5, 2008; U.S. Pat. No. 7,425,833, issued Sep. 16, 2008; U.S. Pat. No. 7,446,536, issued Nov. 4, 2008; U.S. Pat. No. 7,479,763, issued Jan. 20, 2009; U.S. Pat. No. 7,498,767, issued Mar. 3, 2009; U.S. Pat. No. 7,501,795, issued Mar. 10, 2009; U.S. Pat. No. 7,505,856, issued Mar. 17, 2009; U.S. Pat. No. 7,545,146, issued Jun. 9, 2009; U.S. Pat. No. 7,557,586, issued Jul. 7, 2009; U.S. Pat. No. 7,595,643, issued Sep. 29, 2009; U.S. Pat. No. 7,598,699, issued Oct. 6, 2009; U.S. Pat. No. 7,598,744, issued Oct. 6, 2009; U.S. Pat. No. 7,598,743, issued Oct. 6, 2009; U.S. Pat. No. 7,619,417, issued Nov. 17, 2009; U.S. Pat. No. 7,642,786, issued Jan. 5, 2010; U.S. Pat. No. 7,642,787, issued Jan. 5, 2010; U.S. Pat. No. 7,656,162, issued Feb. 2, 2010; U.S. Pat. No. 7,688,074, issued Mar. 30, 2010; U.S. Pat. No. 7,705,602, issued Apr. 27, 2010; U.S. Pat. No. 7,706,992, issued Apr. 27, 2010; U.S. Pat. No. 7,710,119, issued May 4, 2010; U.S. Pat. No. 7,723,993, issued May 25, 2010; U.S. Pat. No. 7,728,597, issued Jun. 1, 2010; U.S. Pat. No. 7,772,850, issued Aug. 10, 2010; U.S. Pat. No. 7,774,151, issued Aug. 10, 2010; U.S. Pat. No. 7,777,612, issued Aug. 17, 2010; U.S. Pat. No. 7,791,348, issued Sep. 7, 2010; U.S. Pat. No. 7,808,375, issued Oct. 5, 2010; U.S. Pat. No. 7,924,015, issued Apr. 12, 2011; U.S. Pat. No. 7,940,053, issued May 10, 2011; U.S. Pat. No. 7,940,052, issued May 10, 2011; U.S. Pat. No. 7,959,476, issued Jun. 14, 2011; U.S. Pat. No. 7,977,914, issued Jul. 12, 2011; U.S. Pat. No. 7,999,505, issued Aug. 16, 2011; U.S. Pat. No. D643,759, issued Aug. 23, 2011; U.S. Pat. No. 8,164,343, issued Apr. 24, 2012; U.S. Pat. No. 8,198,900, issued Jun. 12, 2012; U.S. Pat. No. 8,203,345, issued Jun. 19, 2012; U.S. Pat. No. 8,237,448, issued Aug. 7, 2012; U.S. Pat. No. 8,306,690, issued Nov. 6, 2012; U.S. Pat. No. 8,344,685, issued Jan. 1, 2013; U.S. Pat. No. 8,436,619, issued May 7, 2013; U.S. Pat. No. 8,442,877, issued May 14, 2013; U.S. Pat. No. 8,493,022, issued Jul. 23, 2013; U.S. Pat. No. D687,727, issued Aug. 13, 2013; U.S. Pat. No. 8,513,949, issued Aug. 20, 2013; U.S. Pat. No. 8,674,654, issued Mar. 18, 2014; U.S. Pat. No. 8,674,711, issued Mar. 18, 2014; U.S. Pat. No. 8,704,483, issued Apr. 22, 2014; U.S. Pat. No. 8,738,309, issued May 27, 2014; U.S. Pat. No. 8,754,653, issued Jun. 17, 2014; U.S. Pat. No. 8,872,516, issued Oct. 28, 2014; U.S. Pat. No. 8,872,517, issued Oct. 28, 2014; U.S. Pat. No. 8,958,998, issued Feb. 17, 2015; U.S. Pat. No. 8,963,550, issued Feb. 24, 2015; U.S. Pat. No. 9,018,958, issued Apr. 28, 2015; U.S. Pat. No. 9,052,366, issued Jun. 9, 2015; U.S. Pat. No. 9,201,120, issued Dec. 1, 2015; U.S. Pat. No. 9,229,062, issued Jan. 5, 20126; U.S. Pat. No. 9,274,157, issued Mar. 1, 2016; U.S. Ser. No. 09/780,146, filed Feb. 9, 2001, entitled STORAGE BATTERY WITH INTEGRAL BATTERY TESTER; U.S. Ser. No. 09/756,638, filed Jan. 8, 2001, entitled METHOD AND APPARATUS FOR DETERMINING BATTERY PROPERTIES FROM COMPLEX IMPEDANCE/ADMITTANCE; U.S. Ser. No. 09/862,783, filed May 21, 2001, entitled METHOD AND APPARATUS FOR TESTING CELLS AND BATTERIES EMBEDDED IN SERIES/PARALLEL SYSTEMS; U.S. Ser. No. 09/880,473, filed Jun. 13, 2001; entitled BATTERY TEST MODULE; U.S. Ser. No. 10/109,734, filed Mar. 28, 2002, entitled APPARATUS AND METHOD FOR COUNTERACTING SELF DISCHARGE IN A STORAGE BATTERY; U.S. Ser. No. 10/263,473, filed Oct. 2, 2002, entitled ELECTRONIC BATTERY TESTER WITH RELATIVE TEST OUTPUT; U.S. Ser. No. 09/653,963, filed Sep. 1, 2000, entitled SYSTEM AND METHOD FOR CONTROLLING POWER GENERATION AND STORAGE; U.S. Ser. No. 10/174,110, filed Jun. 18, 2002, entitled DAYTIME RUNNING LIGHT CONTROL USING AN INTELLIGENT POWER MANAGEMENT SYSTEM; U.S. Ser. No. 10/258,441, filed Apr. 9, 2003, entitled CURRENT MEASURING CIRCUIT SUITED FOR BATTERIES; U.S. Ser. No. 10/681,666, filed Oct. 8, 2003, entitled ELECTRONIC BATTERY TESTER WITH PROBE LIGHT; U.S. Ser. No. 60/587,232, filed Dec. 14, 2004, entitled CELLTRON ULTRA, U.S. Ser. No. 60/653,537, filed Feb. 16, 2005, entitled CUSTOMER MANAGED WARRANTY CODE; U.S. Ser. No. 60/665,070, filed Mar. 24, 2005, entitled OHMMETER PROTECTION CIRCUIT; U.S. Ser. No. 60,694,199, filed Jun. 27, 2005, entitled GEL BATTERY CONDUCTANCE COMPENSATION; U.S. Ser. No. 60/705,389, filed Aug. 4, 2005, entitled PORTABLE TOOL THEFT PREVENTION SYSTEM, U.S. Ser. No. 11/207,419, filed Aug. 19, 2005, entitled SYSTEM FOR AUTOMATICALLY GATHERING BATTERY INFORMATION FOR USE DURING BATTERY TESTER/CHARGING, U.S. Ser. No. 60/712,322, filed Aug. 29, 2005, entitled AUTOMOTIVE VEHICLE ELECTRICAL SYSTEM DIAGNOSTIC DEVICE, U.S. Ser. No. 60/713,168, filed Aug. 31, 2005, entitled LOAD TESTER SIMULATION WITH DISCHARGE COMPENSATION, U.S. Ser. No. 60/731,881, filed Oct. 31, 2005, entitled PLUG-IN FEATURES FOR BATTERY TESTERS; U.S. Ser. No. 60/731,887, filed Oct. 31, 2005, entitled AUTOMOTIVE VEHICLE ELECTRICAL SYSTEM DIAGNOSTIC DEVICE; U.S. Ser. No. 60/751,853, filed Dec. 20, 2005, entitled BATTERY MONITORING SYSTEM; U.S. Ser. No. 60/751,853, filed Dec. 20, 2005, entitled BATTERY MONITORING SYSTEM; U.S. Ser. No. 11/356,443, filed Feb. 16, 2006, entitled ELECTRONIC BATTERY TESTER WITH NETWORK COMMUNICATION; U.S. Ser. No. 60/847,064, filed Sep. 25, 2006, entitled STATIONARY BATTERY MONITORING ALGORITHMS; U.S. Ser. No. 60/950,182, filed Jul. 17, 2007, entitled BATTERY TESTER FOR HYBRID VEHICLE; U.S. Ser. No. 60/973,879, filed Sep. 20, 2007, entitled ELECTRONIC BATTERY TESTER FOR TESTING STATIONARY BATTERIES; U.S. Ser. No. 60/992,798, filed Dec. 6, 2007, entitled STORAGE BATTERY AND BATTERY TESTER; U.S. Ser. No. 61/061,848, filed Jun. 16, 2008, entitled KELVIN CLAMP FOR ELECTRONICALLY COUPLING TO A BATTERY CONTACT; U.S. Ser. No. 12/697,485, filed Feb. 1, 2010, entitled ELECTRONIC BATTERY TESTER; U.S. Ser. No. 12/712,456, filed Feb. 25, 2010, entitled METHOD AND APPARATUS FOR DETECTING CELL DETERIORATION IN AN ELECTROCHEMICAL CELL OR BATTERY; U.S. Ser. No. 61/311,485, filed Mar. 8, 2010, entitled BATTERY TESTER WITH DATABUS FOR COMMUNICATING WITH VEHICLE ELECTRICAL SYSTEM; U.S. Ser. No. 61/313,893, filed Mar. 15, 2010, entitled USE OF BATTERY MANUFACTURE/SELL DATE IN DIAGNOSIS AND RECOVERY OF DISCHARGED BATTERIES; U.S. Ser. No. 12/769,911, filed Apr. 29, 2010, entitled STATIONARY BATTERY TESTER; U.S. Ser. No. 61/330,497, filed May 3, 2010, entitled MAGIC WAND WITH ADVANCED HARNESS DETECTION; U.S. Ser. No. 61/348,901, filed May 27, 2010, entitled ELECTRTONIC BATTERY TESTER; U.S Ser. No. 61/351,017, filed Jun. 3, 2010, entitled IMPROVED ELECTRIC VEHICLE AND HYBRID ELECTRIC VEHICLE BATTERY MODULE BALANCER; U.S. Ser. No. 12/818,290, filed Jun. 18, 2010, entitled BATTERY MAINTENANCE DEVICE WITH THERMAL BUFFER; U.S. Ser. No. 61/373,045, filed Aug. 12, 2010, entitled ELECTRONIC BATTERY TESTER FOR TESTING STATIONARY STORAGE BATTERY; U.S. Ser. No. 61/411,162, filed Nov. 8, 2010, entitled ELECTRONIC BATTERY TESTER; U.S. Ser. No. 13/037,641, filed Mar. 1, 2011, entitled :MONITOR FOR FRONT TERMINAL BATTERIES; U.S. Ser. No. 13/098,661, filed May 2, 2011, entitled METHOD AND APPARATUS FOR MEASURING A PARAMETER OF A VEHICLE ELECTRICAL SYSTEM; U.S. Ser. No. 13/152,711, filed Jun. 3, 2011, entitled BATTERY PACK MAINTENANCE FOR ELECTRIC VEHICLE; U.S. Ser. No. 61/558,088, filed Nov. 10, 2011, entitled BATTERY PACK TESTER; U.S. Ser. No. 13/357,306, filed Jan. 24, 2012, entitled STORAGE BATTERY AND BATTERY TESTER; U.S. Ser. No. 61/665,555, filed Jun. 28, 2012, entitled HYBRID AND ELECTRIC VEHICLE BATTERY MAINTENANCE DEVICE; U.S. Ser. No. 13/668,523, filed Nov. 5, 2012, entitled BATTERY TESTER FOR ELECTRIC VEHICLE; U.S. Ser. No. 13/672,186, filed Nov. 8, 2012, entitled BATTERY PACK TESTER; U.S. Ser. No. 61/777,360, filed Mar. 12, 2013, entitled DETERMINATION OF STARTING CURRENT IN AN AUTOMOTIVE VEHICLE; U.S. Ser. No. 61/777,392, filed Mar. 12, 2013, entitled DETERMINATION OF CABLE DROP DURING A STARTING EVENT IN AN AUTOMOTIVE VEHICLE; U.S. Ser. No. 13/827,128, filed Mar. 14, 2013, entitled HYBRID AND ELECTRIC VEHICLE BATTERY MAINTENANCE DEVICE; U.S. Ser. No. 61/789,189, filed Mar. 15, 2013, entitled CURRENT CLAMP WITH JAW CLOSURE DETECTION; U.S. Ser. No. 61/824,056, filed May 16, 2013, entitled BATTERY TESTING SYSTEM AND METHOD; U.S. Ser. No. 61/859,991, filed Jul. 30, 2013, entitled METHOD AND APPARATUS FOR MONITRING A PLURALITY OF STORAGE BATTERIES IN A STATIONARY BACK-UP POWER SYSTEM; U.S. Ser. No. 14/039,746, filed Sep. 27, 2013, entitled BATTERY PACK MAINTENANCE FOR ELECTRIC VEHICLE; U.S. Ser. No. 61/915,157, filed Dec. 12, 2013, entitled BATTERY TESTER AND BATTERY REGISTRATION TOOL; U.S. Ser. No. 61/928,167, filed Jan. 16, 2014, entitled BATTERY CLAMP WITH ENDOSKELETON DESIGN; U.S. Ser. No. 14/204,286, filed Mar. 11, 2014, entitled CURRENT CLAMP WITH JAW CLOSURE DETECTION; U.S. Ser. No. 14/276,276, filed May 13, 2014, entitled BATTERY TESTING SYSTEM AND METHOD; U.S. Ser. No. 62/024,037, filed Jul. 14, 2014, entitled COMBINATION SERVICE TOOL; U.S. Ser. No. 62/055,884, filed Sep. 26, 2014, entitled CABLE CONNECTOR FOR ELECTORNIC BATTERY TESTER; U.S. Ser. No. 14/565,689, filed Dec. 10, 2014, entitled BATTERY TESTER AND BATTERY REGISTRATION TOOL; U.S. Ser. No. 14/598,445, filed Jan. 16, 2015, entitled BATTERY CLAMP WITH ENDOSKELETON DESIGN; U.S. Ser. No. 62/107,648, filed Jan. 26, 2015, entitled ALTERNATOR TESTER; U.S. Ser. No. 62/137,491, filed Mar. 24, 2015, entitled BATTERY MAINTENANCE SYSTEM; U.S. Ser. No. 62/154,251, filed Apr. 29, 2015, entitled CALIBRATION AND PROGRAMMING OF IN-VEHICLE BATTERY SENSORS; U.S. Ser. No. 62/155,045, filed Apr. 30, 2015, entitled CALIBRATION AND PROGRAMMING OF IN-VEHICLE BATTERY SENSORS; U.S. Ser. No. 62/161,555, filed May 14, 2015, entitled ALTERNATOR TESTER, U.S. Ser. No. 14/799,120, filed Jul. 14, 2015, entitled AUTOMOTIVE MAINTENANCE SYSTEM; U.S. Ser. No. 14/861,027, filed Sep. 22, 2015, entitled CABLE CONNECTOR FOR ELECTRONIC BATTERY TESTER; U.S. Ser. No. 62/233,614, filed Sep. 28, 2015, entitled KELVIN CONNECTOR ADAPTOR FOR STORAGE BATTERY; U.S. Ser. No. 15/006,467, filed Jan. 26, 2016, entitled ALTERNATOR TESTER; U.S. Ser. No. 15/017,887, filed Feb. 8, 2016, entitled METHOD AND APPARATUS FOR MEASURING A PARAMETER OF A VEHICLE ELECTRICAL SYSTEM; U.S. Ser. No. 15/049,483, filed Feb. 22, 2016, entitled BATTERY TESTER FOR ELECTRIC VEHICLE; all of which are incorporated herein by reference in their entireties.

### SUMMARY

A battery maintenance system for performing maintenance on a string of storage batteries includes a plurality of battery monitors each of which is configured to electrically couple to a battery in the string of batteries and measure a parameter of the string of batteries. A plurality of controllable electrical loads, each of which are configured to electrically couple to a battery within the string of batteries. The electric loads are controlled during charging of the string of batteries as a function of the measured parameters measured by the plurality of battery monitors.

A method is provided for performing maintenance on a string of batteries includes measuring an electrical parameter of each battery in the string of batteries using a battery monitor connected to batteries in a string of batteries. A charging voltage is applied across the string of batteries. A controllable electric load is applied to at least one of the batteries in the string of batteries based upon an output from a battery monitor.

A battery maintenance system for maintaining a plurality of batteries connected to a battery charger includes at least one sensor module connected to at least one of the plurality of batteries. The sensor module includes first and second electrical connectors which are configured to electrical couple respective positive and negative terminals of the at least one of the plurality of batteries. Battery test circuitry couples to the first and second electrical connectors to measure an electrical parameter of the at least on battery. A controllable electrical load couples to the first and second connectors to apply an electrical load to the at least one battery. A controller coupled to the battery test circuitry and the controllable electrical load controls the controllable electrical load to thereby apply the electrical load to the at least one battery as a function of the measured electrical parameter and thereby control a charging voltage applied to the at least one battery during charging of the plurality of batteries by the battery charger.

### BRIEF DESCRIPTION OF THE DRAWINGS

FIG. 1A is a simplified block diagram of a battery maintenance system in accordance with one example embodiment.

FIG. 1B is a simplified electrical diagram of the battery maintenance system of FIG. 1A.

FIG. 2A is a simplified schematic diagram of one configuration of a switchable load.

FIG. 2B is a simplified schematic diagram of another example configuration of a switchable load configured as a variable load.

### DETAILED DESCRIPTION OF ILLUSTRATIVE EMBODIMENTS

Standby batteries (used as a back-up power source for telecommunications, computing and other power-sensitive applications) are typically arranged in an array, or string, to create a desired voltage level. These strings consist of single or multiple cell modules and the connection may be parallel, series and/or series/parallel. Research has demonstrated that these like units, when in the application, will often reach a state where there is variation among the voltage or charge levels of the battery modules. This phenomenon, called voltage imbalance, has been demonstrated to reduce the useable life of the modules in the string as the imbalance results in uneven charge requirements that drive degradation within the modules. The invention includes of a method for intelligent battery management of a battery string consisting of a sensing device (sensor also referred to herein as sensor module, battery test circuitry and battery monitor), connected to the batteries individually through a four-point Kelvin connection. The sensor measures individual battery dynamic parameters such as dynamic conductance using Kelvin battery monitoring and statistically derives battery information from voltage discharge battery equalization to identify and manage weak or bad batteries. The sensor then selectively applies an integrated current load during charging to drive a charging response from the connected battery charging system to create a balancing effect and thereby extend battery life and maximize charging of the array.

Preferably, a battery string comprised of N series connected batteries are “float” charged by a constant voltage charger, such that all batteries in the series string “float” to the same string voltage average and thus all batteries have the same voltage measurement reading. However, weak or partially charged batteries create a string battery voltage imbalance that increases the remaining battery voltages from the string battery voltage average, while the weak or partially charged battery has a battery voltage which is less than the string battery average. Historically, batteries with a voltage beyond a defined “float” voltage tolerance limit from the string battery voltage average experience a reduced service life. The problem to solve is to control the battery voltage from exceeding the “float” voltage tolerance for the purpose of preventing a sub-average battery service life.

A method and apparatus for controlling and managing a battery voltage in a string comprising of N series batteries while the batteries are “float” charged with a constant voltage charger is provided. A battery voltage control mechanism for decreasing higher voltage batteries from the “float” average includes of a switchable (variable) load with Kelvin wired connections. The switchable load is applied for a fixed time interval to partially discharge the targeted battery through the wired Kelvin connections, thus reducing the target battery voltage from the string average. In on configuration, the switchable load comprises is adjustable (either continuously or in one or more steps) and may comprise loads of differing resistance values. The adjustments may be continuous or may be stepped and may include more than one fixed resistance level. The remaining unloaded battery voltages will increase proportionally since the constant voltage charger maintains a constant average battery voltage (across the string). Low voltage batteries will thus have an incremental voltage rise while the battery voltage decreases on the targeted battery that was partially discharged with a switchable load.

In One Example Battery Maintenance System Capabilities Include:
1) Battery conductance measurement using a partial battery discharge capacity perturbation method using kelvin voltage and current monitoring.
   a. The battery maintenance system estimates battery state of health since battery conductance is directly proportional to battery energy capacity
2) Negative battery post temperature measurement during the conductance measurement period
   a. The battery maintenance system identifies accelerated battery temperature gradients from the average string battery temperature.
   b. A large battery temperature gradient predicts a battery trend towards thermal runaway during a significant current discharge cycle when a UPS power outage condition exists.
3) Measure battery voltage dynamics with selective battery conductance measurements to statistically identify weak or bad batteries.
   a. Battery voltage equalization is employed to statistically derive a batteries ability to hold a charge
      i. Battery exceeding the battery float voltage threshold is targeted for conductance testing
      ii. Detects a fast decreasing voltage during a conductance measurement
      iii. Detects slow decreasing voltage during a conductance measurement
      iv. Detects a near constant or disproportionate battery increase during an adjacent battery conductance measurement cycle.
4) Perform measurements and methods in an active UPS with battery string connected to a constant voltage charger
5) BATTERY MAINTENANCE SYSTEM capabilities are functionally exercised to create a statistically holistic view of the health of the battery with prescribed reporting and pro-active maintenance customer actions.

### EXAMPLE ALGORITHM STEPS

1) Conductance battery measurements are sequenced from the highest voltage battery to the lowest voltage battery. Perform conductance measurement on batteries that have a voltage greater than V_BATTERY_THRESHOLD.
2) Create battery conductance indices to rate the battery conductance relative to the string conductance average
3) Measure the negative battery post temperature before and after the conductance measurement period
4) Create battery temperature indices to rate the battery temperature, after the conductance measurement period, relative to the string battery negative post average.
5) Create battery temperature indices to rate the battery temperature gradient, during the conductance measurement period, relative to the string battery negative post average.
6) Analyze data for a low voltage battery condition, high voltage battery condition, open battery trend condition, and excessive thermal battery conditions.
7) Create state of health indices from analyzed data, and post identified alarm conditions
8) Disable conductance measurements and send alarm messages if the battery voltage exceeds critical voltage thresholds
9) Disable conductance measurements and send alarm messages if the battery conductance is less than a critical conductance threshold
10) Disable conductance measurements and send alarm messages if the battery negative post temperature exceeded a critical temperature threshold.

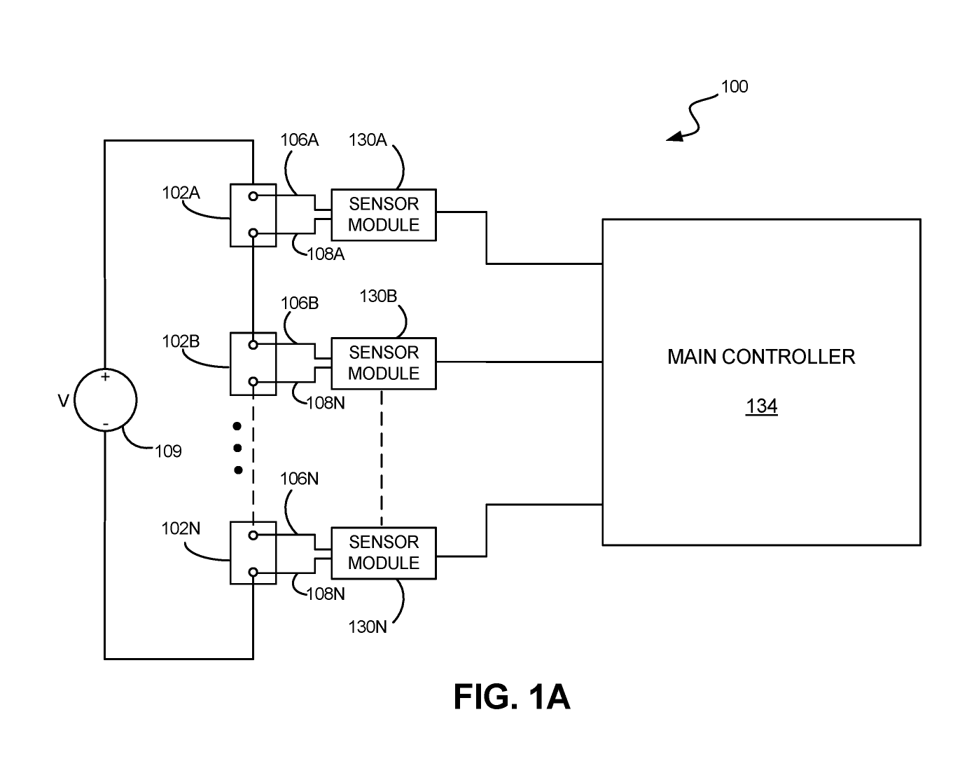

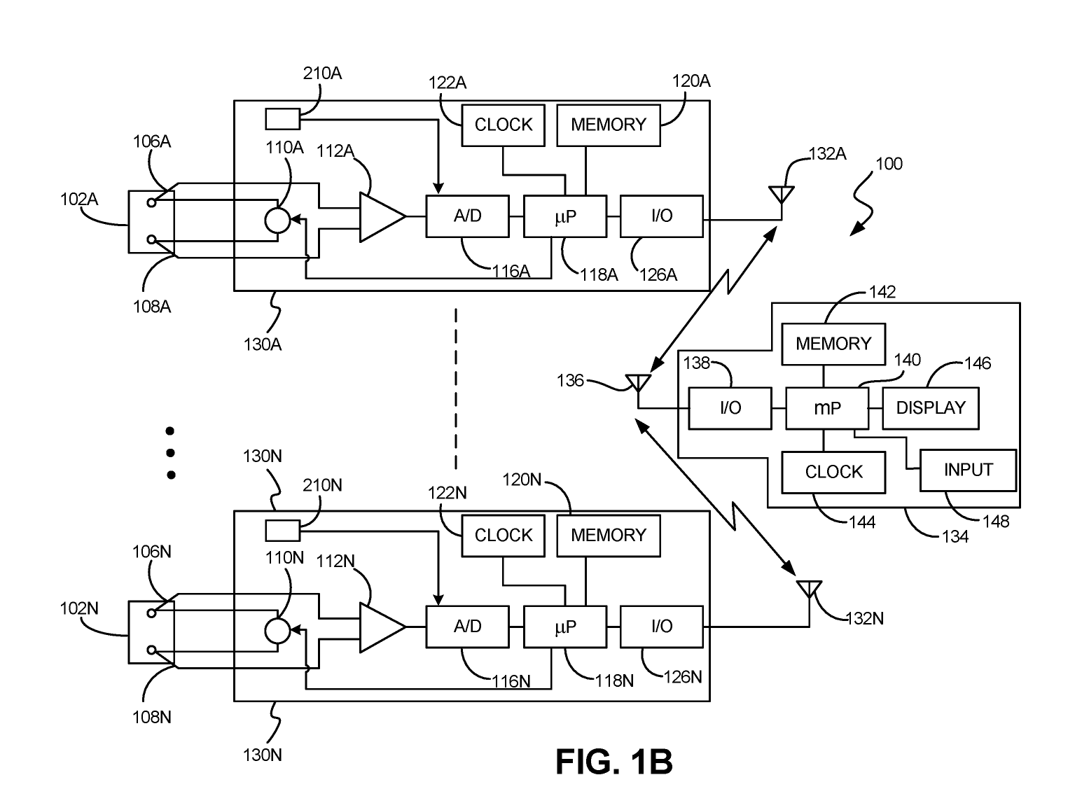

FIG. 1A is a simplified block diagram showing a battery maintenance system 100 connected to a plurality of batteries 102A, 102B . . . 102N. A plurality of sensor modules 130A, 130B . . . 130N are connected to respective batteries through Kelvin connectors 106A/108A, 106B/108B . . . 106N/108N. The Kelvin connections 106, 108 connect to respective positive and negative terminals of each of the batteries 102. As illustrated in FIG. 1A, the batteries 102 are electrically connected in series. However, the connections may also be in parallel and/or series/parallel. A charging source 109 is illustrated as a voltage source connected across the plurality of batteries 102. The individual sensor modules 130 are connected to an optional main controller 134. The connection may be through a wired connection such as through a databus, or may be through a wireless connection including standardized wireless connections such as Bluetooth, WiFi, etc. As illustrated in FIG. 1A, the battery charger 109 is only capable of controlling the voltage (and/or current) applied to opposed ends of the plurality of batteries. Thus, control of the voltage and/or current applied to individual batteries cannot be performed using the battery charger 109. As discussed above, this can lead to inefficient charging of the individual batteries 102 and may even cause damage to individual batteries 102 within the plurality of batteries. As discussed herein, the sensor modules 130 allow for some control to the voltage and/or current applied to the individual batteries 102 by controlling a value of a load applied across the individual batteries 102.

FIG. 1B is a simplified diagram showing another example embodiment of the present invention in which wireless test modules 130A . . . 130N are coupled to respective batteries 102A . . . 102N. Each of the test modules includes a forcing function 112, a response sensor such as differential sense amplifier 112, an analog to digital converter 116, a microprocessor 118, a memory 120, a clock 122, an input/output circuitry 126. In one example configuration, the forcing function 110 is provided by the battery charger 109 illustrated in FIG. 1A. in such a configuration, the current through the battery may be sensed, or the voltage across the battery may be sensed, and the current or voltage, respectively, measured in order to obtain a dynamic parameter. In FIG. 1B, the input/output circuitry 126 is configured to wireless communication through an antenna 132. In one configuration, circuitry 126 is configured only for transmitting information whereas in another example configuration, circuitry 126 is configured for both transmitting and receiving information. Although a microprocessor 118 is illustrated, any type of controller can be used, including one implemented in simplified digital circuitry, or even analog circuitry. Modules 130 are configured to measure parameters of batteries 102 as described herein. Information related to measured parameters is provided to a centralized diagnostic system 134. Main controller 134 includes input/output circuitry 138 configured to wirelessly communicate with modules 130 through an antenna 136. The communication is controlled by microprocessor 140 which operates in accordance with instructions stored in a memory 142 and at a clock rate determined by clock 144. A display 146 is illustrated for displaying information to an operator. Similarly, input circuitry 148 is provided to receiving an input from an operator. Additionally, input circuitry 148 can be configured as input/output circuitry and used to communication with other systems, for example, and used to communicate with other systems, such as a remote database, a remote location, etc. Memory 132 is further configured for storing measured parameters from batteries 102 in a database whereby the measured parameter is recorded as is the information related to the time at which the parameter was obtained and the battery from which the parameter was obtained. The communication between module 130 and main controller 134 may be through any appropriate format. For example, radio frequency (RF) type formats may be employed including those which utilize industry standards such as Bluetooth®, WiFi techniques, etc.

The system 100 can measure any electrical parameter of the batteries 102. In one specific example, the measured parameter comprises a dynamic parameter in which a forcing function is applied to a battery and a response measured. The forcing function can include a time varying component including transient as well as periodic components. The forcing function can be large or small relative to the voltage of the battery 102 or the current flowing through the battery 102. The resultant signal (i.e. voltage) change across terminals of a battery is measured using differential sense amplifier 112. The forcing function can be active source in which power is applied to the battery, for example, using a transistor driven source. Similarly, the forcing function may comprise a passive source in which power is drawn from the battery, for example using such as a load resistance, etc. The forcing function signal can be any signal having a time varying component including periodic and transient signals. Microprocessor 118 can calculate a dynamic parameter based upon the forcing function and the measured response. Note in another example configuration the microprocessor 140 as shown in main controller 134 can be used to determine the dynamic parameter. Additionally, in other configurations, analog circuitry can be used to measure the dynamic parameter. For example, dynamic conductance can be calculated as follows:

ΔG=ΔI/ΔV Equation 1

Other examples include dynamic resistance, impedance, susceptance, admittance, etc. Examples of dynamic parameter measurements and related technology are shown in and described in U.S. Pat. No. 3,873,911, issued Mar. 25, 1975, to Champlin; U.S. Pat. No. 3,909,708, issued Sep. 30, 1975, to Champlin; U.S. Pat. No. 4,816,768, issued Mar. 28, 1989, to Champlin; U.S. Pat. No. 4,825,170, issued Apr. 25, 1989, to Champlin; U.S. Pat. No. 4,881,038, issued Nov. 14, 1989, to Champlin; U.S. Pat. No. 4,912,416, issued Mar. 27, 1990, to Champlin; U.S. Pat. No. 5,140,269, issued Aug. 18, 1992, to Champlin; U.S. Pat. No. 5,343,380, issued Aug. 30, 1994; U.S. Pat. No. 5,572,136, issued Nov. 5, 1996; U.S. Pat. No. 5,574,355, issued Nov. 12, 1996; U.S. Pat. No. 5,583,416, issued Dec. 10, 1996; U.S. Pat. No. 5,585,728, issued Dec. 17, 1996; U.S. Pat. No. 5,589,757, issued Dec. 31, 1996; U.S. Pat. No. 5,592,093, issued Jan. 7, 1997; U.S. Pat. No. 5,598,098, issued Jan. 28, 1997; U.S. Pat. No. 5,656,920, issued Aug. 12, 1997; U.S. Pat. No. 5,757,192, issued May 26, 1998; U.S. Pat. No. 5,821,756, issued Oct. 13, 1998; U.S. Pat. No. 5,831,435, issued Nov. 3, 1998; U.S. Pat. No. 5,871,858, issued Feb. 16, 1999; U.S. Pat. No. 5,914,605, issued Jun. 22, 1999; U.S. Pat. No. 5,945,829, issued Aug. 31, 1999; U.S. Pat. No. 6,002,238, issued Dec. 14, 1999; U.S. Pat. No. 6,037,751, issued Mar. 14, 2000; U.S. Pat. No. 6,037,777, issued Mar. 14, 2000; U.S. Pat. No. 6,051,976, issued Apr. 18, 2000; U.S. Pat. No. 6,081,098, issued Jun. 27, 2000; U.S. Pat. No. 6,091,245, issued Jul. 18, 2000; U.S. Pat. No. 6,104,167, issued Aug. 15, 2000; U.S. Pat. No. 6,137,269, issued Oct. 24, 2000; U.S. Pat. No. 6,163,156, issued Dec. 19, 2000; U.S. Pat. No. 6,172,483, issued Jan. 9, 2001; U.S. Pat. No. 6,172,505, issued Jan. 9, 2001; U.S. Pat. No. 6,222,369, issued Apr. 24, 2001; U.S. Pat. No. 6,225,808, issued May 1, 2001; U.S. Pat. No. 6,249,124, issued Jun. 19, 2001; U.S. Pat. No. 6,259,254, issued Jul. 10, 2001; U.S. Pat. No. 6,262,563, issued Jul. 17, 2001; U.S. Pat. No. 6,294,896, issued Sep. 25, 2001; U.S. Pat. No. 6,294,897, issued Sep. 25, 2001; U.S. Pat. No. 6,304,087, issued Oct. 16, 2001; U.S. Pat. No. 6,310,481, issued Oct. 30, 2001; U.S. Pat. No. 6,313,607, issued Nov. 6, 2001; U.S. Pat. No. 6,313,608, issued Nov. 6, 2001; U.S. Pat. No. 6,316,914, issued Nov. 13, 2001; U.S. Pat. No. 6,323,650, issued Nov. 27, 2001; U.S. Pat. No. 6,329,793, issued Dec. 11, 2001; U.S. Pat. No. 6,331,762, issued Dec. 18, 2001; U.S. Pat. No. 6,332,113, issued Dec. 18, 2001; U.S. Pat. No. 6,351,102, issued Feb. 26, 2002; U.S. Pat. No. 6,359,441, issued Mar. 19, 2002; U.S. Pat. No. 6,363,303, issued Mar. 26, 2002; U.S. Pat. No. 6,377,031, issued Apr. 23, 2002; U.S. Pat. No. 6,392,414, issued May 21, 2002; U.S. Pat. No. 6,417,669, issued Jul. 9, 2002; U.S. Pat. No. 6,424,158, issued Jul. 23, 2002; U.S. Pat. No. 6,441,585, issued Aug. 17, 2002; U.S. Pat. No. 6,437,957, issued Aug. 20, 2002; U.S. Pat. No. 6,445,158, issued Sep. 3, 2002; U.S. Pat. No. 6,456,045; U.S. Pat. No. 6,466,025, issued Oct. 15, 2002; U.S. Pat. No. 6,465,908, issued Oct. 15, 2002; U.S. Pat. No. 6,466,026, issued Oct. 15, 2002; U.S. Pat. No. 6,469,511, issued Nov. 22, 2002; U.S. Pat. No. 6,495,990, issued Dec. 17, 2002; U.S. Pat. No. 6,497,209, issued Dec. 24, 2002; U.S. Pat. No. 6,507,196, issued Jan. 14, 2003; U.S. Pat. No. 6,534,993; issued Mar. 18, 2003; U.S. Pat. No. 6,544,078, issued Apr. 8, 2003; U.S. Pat. No. 6,556,019, issued Apr. 29, 2003; U.S. Pat. No. 6,566,883, issued May 20, 2003; U.S. Pat. No. 6,586,941, issued Jul. 1, 2003; U.S. Pat. No. 6,597,150, issued Jul. 22, 2003; U.S. Pat. No. 6,621,272, issued Sep. 16, 2003; U.S. Pat. No. 6,623,314, issued Sep. 23, 2003; U.S. Pat. No. 6,633,165, issued Oct. 14, 2003; U.S. Pat. No. 6,635,974, issued Oct. 21, 2003; U.S. Pat. No. 6,696,819, issued Feb. 24, 20144; U.S. Pat. No. 6,707,303, issued Mar. 16, 2004; U.S. Pat. No. 6,737,831, issued May 18, 2004; U.S. Pat. No. 6,744,149, issued Jun. 1, 2004; U.S. Pat. No. 6,759,849, issued Jul. 6, 2004; U.S. Pat. No. 6,781,382, issued Aug. 24, 2004; U.S. Pat. No. 6,788,025, filed Sep. 7, 2004; U.S. Pat. No. 6,795,782, issued Sep. 21, 2004; U.S. Pat. No. 6,805,090, filed Oct. 19, 2004; U.S. Pat. No. 6,806,716, filed Oct. 19, 2004; U.S. Pat. No. 6,850,037, filed Feb. 1, 2005; U.S. Pat. No. 6,850,037, issued Feb. 1, 2005; U.S. Pat. No. 6,871,151, issued Mar. 22, 2005; U.S. Pat. No. 6,885,195, issued Apr. 26, 2005; U.S. Pat. No. 6,888,468, issued May 3, 2005; U.S. Pat. No. 6,891,378, issued May 10, 2005; U.S. Pat. No. 6,906,522, issued Jun. 14, 2005; U.S. Pat. No. 6,906,523, issued Jun. 14, 2005; U.S. Pat. No. 6,909,287, issued Jun. 21, 2005; U.S. Pat. No. 6,914,413, issued Jul. 5, 2005; U.S. Pat. No. 6,913,483, issued Jul. 5, 2005; U.S. Pat. No. 6,930,485, issued Aug. 16, 2005; U.S. Pat. No. 6,933,727, issued Aug. 23, 200; U.S. Pat. No. 6,941,234, filed Sep. 6, 2005; U.S. Pat. No. 6,967,484, issued Nov. 22, 2005; U.S. Pat. No. 6,998,847, issued Feb. 14, 2006; U.S. Pat. No. 7,003,410, issued Feb. 21, 2006; U.S. Pat. No. 7,003,411, issued Feb. 21, 2006; U.S. Pat. No. 7,012,433, issued Mar. 14, 2006; U.S. Pat. No. 7,015,674, issued Mar. 21, 2006; U.S. Pat. No. 7,034,541, issued Apr. 25, 2006; U.S. Pat. No. 7,039,533, issued May 2, 2006; U.S. Pat. No. 7,058,525, issued Jun. 6, 2006; U.S. Pat. No. 7,081,755, issued Jul. 25, 2006; U.S. Pat. No. 7,106,070, issued Sep. 12, 2006; U.S. Pat. No. 7,116,109, issued Oct. 3, 2006; U.S. Pat. No. 7,119,686, issued Oct. 10, 2006; and U.S. Pat. No. 7,126,341, issued Oct. 24, 2006; U.S. Pat. No. 7,154,276, issued Dec. 26, 2006; U.S. Pat. No. 7,198,510, issued Apr. 3, 2007; U.S. Pat. No. 7,363,175, issued Apr. 22, 2008; U.S. Pat. No. 7,208,914, issued Apr. 24, 2007; U.S. Pat. No. 7,246,015, issued Jul. 17, 2007; U.S. Pat. No. 7,295,936, issued Nov. 13, 2007; U.S. Pat. No. 7,319,304, issued Jan. 15, 2008; U.S. Pat. No. 7,363,175, issued Apr. 22, 2008; U.S. Pat. No. 7,398,176, issued Jul. 8, 2008; U.S. Pat. No. 7,408,358, issued Aug. 5, 2008; U.S. Pat. No. 7,425,833, issued Sep. 16, 2008; U.S. Pat. No. 7,446,536, issued Nov. 4, 2008; U.S. Pat. No. 7,479,763, issued Jan. 20, 2009; U.S. Pat. No. 7,498,767, issued Mar. 3, 2009; U.S. Pat. No. 7,501,795, issued Mar. 10, 2009; U.S. Pat. No. 7,505,856, issued Mar. 17, 2009; U.S. Pat. No. 7,545,146, issued Jun. 9, 2009; U.S. Pat. No. 7,557,586, issued Jul. 7, 2009; U.S. Pat. No. 7,595,643, issued Sep. 29, 2009; U.S. Pat. No. 7,598,699, issued Oct. 6, 2009; U.S. Pat. No. 7,598,744, issued Oct. 6, 2009; U.S. Pat. No. 7,598,743, issued Oct. 6, 2009; U.S. Pat. No. 7,619,417, issued Nov. 17, 2009; U.S. Pat. No. 7,642,786, issued Jan. 5, 2010; U.S. Pat. No. 7,642,787, issued Jan. 5, 2010; U.S. Pat. No. 7,656,162, issued Feb. 2, 2010; U.S. Pat. No. 7,688,074, issued Mar. 30, 2010; U.S. Pat. No. 7,705,602, issued Apr. 27, 2010; U.S. Pat. No. 7,706,992, issued Apr. 27, 2010; U.S. Pat. No. 7,710,119, issued May 4, 2010; U.S. Pat. No. 7,723,993, issued May 25, 2010; U.S. Pat. No. 7,728,597, issued Jun. 1, 2010; U.S. Pat. No. 7,772,850, issued Aug. 10, 2010; U.S. Pat. No. 7,774,151, issued Aug. 10, 2010; U.S. Pat. No. 7,777,612, issued Aug. 17, 2010; U.S. Pat. No. 7,791,348, issued Sep. 7, 2010; U.S. Pat. No. 7,808,375, issued Oct. 5, 2010; U.S. Pat. No. 7,924,015, issued Apr. 12, 2011; U.S. Pat. No. 7,940,053, issued May 10, 2011; U.S. Pat. No. 7,940,052, issued May 10, 2011; U.S. Pat. No. 7,959,476, issued Jun. 14, 2011; U.S. Pat. No. 7,977,914, issued Jul. 12, 2011; U.S. Pat. No. 7,999,505, issued Aug. 16, 2011; U.S. Pat. No. D643,759, issued Aug. 23, 2011; U.S. Pat. No. 8,164,343, issued Apr. 24, 2012; U.S. Pat. No. 8,198,900, issued Jun. 12, 2012; U.S. Pat. No. 8,203,345, issued Jun. 19, 2012; U.S. Pat. No. 8,237,448, issued Aug. 7, 2012; U.S. Pat. No. 8,306,690, issued Nov. 6, 2012; U.S. Pat. No. 8,344,685, issued Jan. 1, 2013; U.S. Pat. No. 8,436,619, issued May 7, 2013; U.S. Pat. No. 8,442,877, issued May 14, 2013; U.S. Pat. No. 8,493,022, issued Jul. 23, 2013; U.S. Pat. No. D687,727, issued Aug. 13, 2013; U.S. Pat. No. 8,513,949, issued Aug. 20, 2013; U.S. Pat. No. 8,674,654, issued Mar. 18, 2014; U.S. Pat. No. 8,674,711, issued Mar. 18, 2014; U.S. Pat. No. 8,704,483, issued Apr. 22, 2014; U.S. Pat. No. 8,738,309, issued May 27, 2014; U.S. Pat. No. 8,754,653, issued Jun. 17, 2014; U.S. Pat. No. 8,872,516, issued Oct. 28, 2014; U.S. Pat. No. 8,872,517, issued Oct. 28, 2014; U.S. Pat. No. 8,958,998, issued Feb. 17, 2015; U.S. Pat. No. 8,963,550, issued Feb. 24, 2015; U.S. Pat. No. 9,018,958, issued Apr. 28, 2015; U.S. Pat. No. 9,052,366, issued Jun. 9, 2015; U.S. Pat. No. 9,201,120, issued Dec. 1, 2015; U.S. Pat. No. 9,229,062, issued Jan. 5, 20126; U.S. Pat. No. 9,274,157, issued Mar. 1, 2016; U.S. Ser. No. 09/780,146, filed Feb. 9, 2001, entitled STORAGE BATTERY WITH INTEGRAL BATTERY TESTER; U.S. Ser. No. 09/756,638, filed Jan. 8, 2001, entitled METHOD AND APPARATUS FOR DETERMINING BATTERY PROPERTIES FROM COMPLEX IMPEDANCE/ADMITTANCE; U.S. Ser. No. 09/862,783, filed May 21, 2001, entitled METHOD AND APPARATUS FOR TESTING CELLS AND BATTERIES EMBEDDED IN SERTES/PARALLEL SYSTEMS; U.S. Ser. No. 09/880,473, filed Jun. 13, 2001; entitled BATTERY TEST MODULE; U.S. Ser. No. 10/109,734, filed Mar. 28, 2002, entitled APPARATUS AND METHOD FOR COUNTERACTING SELF DISCHARGE IN A STORAGE BATTERY; U.S. Ser. No. 10/263,473, filed Oct. 2, 2002, entitled ELECTRONIC BATTERY TESTER WITH RELATIVE TEST OUTPUT; U.S. Ser. No. 09/653,963, filed Sep. 1, 2000, entitled SYSTEM AND METHOD FOR CONTROLLING POWER GENERATION AND STORAGE; U.S. Ser. No. 10/174,110, filed Jun. 18, 2002, entitled DAYTIME RUNNING LIGHT CONTROL USING AN INTELLIGENT POWER MANAGEMENT SYSTEM; U.S. Ser. No. 10/258,441, filed Apr. 9, 2003, entitled CURRENT MEASURING CIRCUIT SUITED FOR BATTERIES; U.S. Ser. No. 10/681,666, filed Oct. 8, 2003, entitled ELECTRONIC BATTERY TESTER WITH PROBE LIGHT; U.S. Ser. No. 60/587,232, filed Dec. 14, 2004, entitled CELLTRON ULTRA, U.S. Ser. No. 60/653,537, filed Feb. 16, 2005, entitled CUSTOMER MANAGED WARRANTY CODE; U.S. Ser. No. 60/665,070, filed Mar. 24, 2005, entitled OHMMETER PROTECTION CIRCUIT; U.S. Ser. No. 60,694,199, filed Jun. 27, 2005, entitled GEL BATTERY CONDUCTANCE COMPENSATION; U.S. Ser. No. 60/705,389, filed Aug. 4, 2005, entitled PORTABLE TOOL THEFT PREVENTION SYSTEM, U.S. Ser. No. 11/207,419, filed Aug. 19, 2005, entitled SYSTEM FOR AUTOMATICALLY GATHERING BATTERY INFORMATION FOR USE DURING BATTERY TESTER/CHARGING, U.S. Ser. No. 60/712,322, filed Aug. 29, 2005, entitled AUTOMOTIVE VEHICLE ELECTRICAL SYSTEM DIAGNOSTIC DEVICE, U.S. Ser. No. 60/713,168, filed Aug. 31, 2005, entitled LOAD TESTER SIMULATION WITH DISCHARGE COMPENSATION, U.S. Ser. No. 60/731,881, filed Oct. 31, 2005, entitled PLUG-IN FEATURES FOR BATTERY TESTERS; U.S. Ser. No. 60/731,887, filed Oct. 31, 2005, entitled AUTOMOTIVE VEHICLE ELECTRICAL SYSTEM DIAGNOSTIC DEVICE; U.S. Ser. No. 60/751,853, filed Dec. 20, 2005, entitled BATTERY MONITORING SYSTEM; U.S. Ser. No. 60/751,853, filed Dec. 20, 2005, entitled BATTERY MONITORING SYSTEM; U.S. Ser. No. 11/356,443, filed Feb. 16, 2006, entitled ELECTRONIC BATTERY TESTER WITH NETWORK COMMUNICATION; U.S. Ser. No. 60/847,064, filed Sep. 25, 2006, entitled STATIONARY BATTERY MONITORING ALGORITHMS; U.S. Ser. No. 60/950,182, filed Jul. 17, 2007, entitled BATTERY TESTER FOR HYBRID VEHICLE; U.S. Ser. No. 60/973,879, filed Sep. 20, 2007, entitled ELECTRONIC BATTERY TESTER FOR TESTING STATIONARY BATTERIES; U.S. Ser. No. 60/992,798, filed Dec. 6, 2007, entitled STORAGE BATTERY AND BATTERY TESTER; U.S. Ser. No. 61/061,848, filed Jun. 16, 2008, entitled KELVIN CLAMP FOR ELECTRONICALLY COUPLING TO A BATTERY CONTACT; U.S. Ser. No. 12/697,485, filed Feb. 1, 2010, entitled ELECTRONIC BATTERY TESTER; U.S. Ser. No. 12/712,456, filed Feb. 25, 2010, entitled METHOD AND APPARATUS FOR DETECTING CELL DETERIORATION IN AN ELECTROCHEMICAL CELL OR BATTERY; U.S. Ser. No. 61/311,485, filed Mar. 8, 2010, entitled BATTERY TESTER WITH DATABUS FOR COMMUNICATING WITH VEHICLE ELECTRICAL SYSTEM; U.S. Ser. No. 61/313,893, filed Mar. 15, 2010, entitled USE OF BATTERY MANUFACTURE/SELL DATE IN DIAGNOSIS AND RECOVERY OF DISCHARGED BATTERIES; U.S. Ser. No. 12/769,911, filed Apr. 29, 2010, entitled STATIONARY BATTERY TESTER; U.S. Ser. No. 61/330,497, filed May 3, 2010, entitled MAGIC WAND WITH ADVANCED HARNESS DETECTION; U.S. Ser. No. 61/348,901, filed May 27, 2010, entitled ELECTRTONIC BATTERY TESTER; U.S. Ser. No. 61/351,017, filed Jun. 3, 2010, entitled IMPROVED ELECTRIC VEHICLE AND HYBRID ELECTRIC VEHICLE BATTERY MODULE BALANCER; U.S. Ser. No. 12/818,290, filed Jun. 18, 2010, entitled BATTERY MAINTENANCE DEVICE WITH THERMAL BUFFER; U.S. Ser. No. 61/373,045, filed Aug. 12, 2010, entitled ELECTRONIC BATTERY TESTER FOR TESTING STATIONARY STORAGE BATTERY; U.S. Ser. No. 61/411,162, filed Nov. 8, 2010, entitled ELECTRONIC BATTERY TESTER; U.S. Ser. No. 13/037,641, filed Mar. 1, 2011, entitled :MONITOR FOR FRONT TERMINAL BATTERIES; U.S. Ser. No. 13/098,661, filed May 2, 2011, entitled METHOD AND APPARATUS FOR MEASURING A PARAMETER OF A VEHICLE ELECTRICAL SYSTEM; U.S. Ser. No. 13/152,711, filed Jun. 3, 2011, entitled BATTERY PACK MAINTENANCE FOR ELECTRIC VEHICLE; U.S. Ser. No. 61/558,088, filed Nov. 10, 2011, entitled BATTERY PACK TESTER; U.S. Ser. No. 13/357,306, filed Jan. 24, 2012, entitled STORAGE BATTERY AND BATTERY TESTER; U.S. Ser. No. 61/665,555, filed Jun. 28, 2012, entitled HYBRID AND ELECTRIC VEHICLE BATTERY MAINTENANCE DEVICE; U.S. Ser. No. 13/668,523, filed Nov. 5, 2012, entitled BATTERY TESTER FOR ELECTRIC VEHICLE; U.S. Ser. No. 13/672,186, filed Nov. 8, 2012, entitled BATTERY PACK TESTER; U.S. Ser. No. 61/777,360, filed Mar. 12, 2013, entitled DETERMINATION OF STARTING CURRENT IN AN AUTOMOTIVE VEHICLE; U.S. Ser. No. 61/777,392, filed Mar. 12, 2013, entitled DETERMINATION OF CABLE DROP DURING A STARTING EVENT IN AN AUTOMOTIVE VEHICLE; U.S. Ser. No. 13/827,128, filed Mar. 14, 2013, entitled HYBRID AND ELECTRIC VEHICLE BATTERY MAINTENANCE DEVICE; U.S. Ser. No. 61/789,189, filed Mar. 15, 2013, entitled CURRENT CLAMP WITH JAW CLOSURE DETECTION; U.S. Ser. No. 61/824,056, filed May 16, 2013, entitled BATTERY TESTING SYSTEM AND METHOD; U.S. Ser. No. 61/859,991, filed Jul. 30, 2013, entitled METHOD AND APPARATUS FOR MONITRING A PLURALITY OF STORAGE BATTERIES IN A STATIONARY BACK-UP POWER SYSTEM; U.S. Ser. No. 14/039,746, filed Sep. 27, 2013, entitled BATTERY PACK MAINTENANCE FOR ELECTRIC VEHICLE; U.S. Ser. No. 61/915,157, filed Dec. 12, 2013, entitled BATTERY TESTER AND BATTERY REGISTRATION TOOL; U.S. Ser. No. 61/928,167, filed Jan. 16, 2014, entitled BATTERY CLAMP WITH ENDOSKELETON DESIGN; U.S. Ser. No. 14/204,286, filed Mar. 11, 2014, entitled CURRENT CLAMP WITH JAW CLOSURE DETECTION; U.S. Ser. No. 14/276,276, filed May 13, 2014, entitled BATTERY TESTING SYSTEM AND METHOD; U.S. Ser. No. 62/024,037, filed Jul. 14, 2014, entitled COMBINATION SERVICE TOOL; U.S. Ser. No. 62/055,884, filed Sep. 26, 2014, entitled CABLE CONNECTOR FOR ELECTORNIC BATTERY TESTER; U.S. Ser. No. 14/565,689, filed Dec. 10, 2014, entitled BATTERY TESTER AND BATTERY REGISTRATION TOOL; U.S. Ser. No. 14/598,445, filed Jan. 16, 2015, entitled BATTERY CLAMP WITH ENDOSKELETON DESIGN; U.S. Ser. No. 62/107,648, filed Jan. 26, 2015, entitled ALTERNATOR TESTER; U.S. Ser. No. 62/137,491, filed Mar. 24, 2015, entitled BATTERY MAINTENANCE SYSTEM; U.S. Ser. No. 62/154,251, filed Apr. 29, 2015, entitled CALIBRATION AND PROGRAMMING OF IN-VEHICLE BATTERY SENSORS; U.S. Ser. No. 62/155,045, filed Apr. 30, 2015, entitled CALIBRATION AND PROGRAMMING OF IN-VEHICLE BATTERY SENSORS; U.S. Ser. No. 62/161,555, filed May 14, 2015, entitled ALTERNATOR TESTER, U.S. Ser. No. 14/799,120, filed Jul. 14, 2015, entitled AUTOMOTIVE MAINTENANCE SYSTEM; U.S. Ser. No. 14/861,027, filed Sep. 22, 2015, entitled CABLE CONNECTOR FOR ELECTRONIC BATTERY TESTER; U.S. Ser. No. 62/233,614, filed Sep. 28, 2015, entitled KELVIN CONNECTOR ADAPTOR FOR STORAGE BATTERY; U.S. Ser. No. 15/006,467, filed Jan. 26, 2016, entitled ALTERNATOR TESTER; U.S. Ser. No. 15/017,887, filed Feb. 8, 2016, entitled METHOD AND APPARATUS FOR MEASURING A PARAMETER OF A VEHICLE ELECTRICAL SYSTEM; U.S. Ser. No. 15/049,483, filed Feb. 22, 2016, entitled BATTERY TESTER FOR ELECTRIC VEHICLE; all of which are incorporated herein by reference in their entireties.

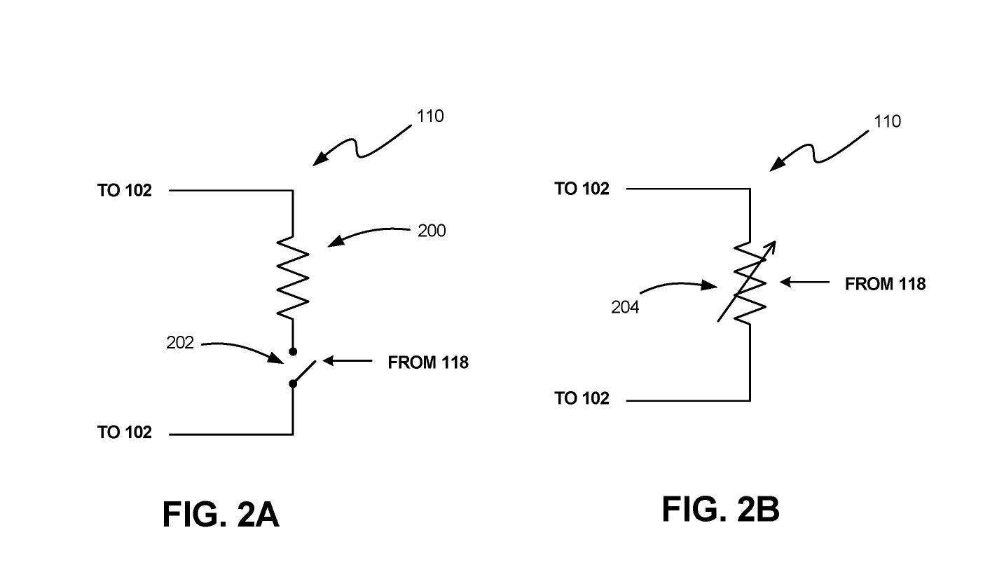

As discussed above, the system 100 can be configured to apply a switchable or variable load to individual batteries 102 based upon dynamic measurements, or even static voltage measurements, during charging in order to achieve a desired voltage across individual batteries 102 in the string of batteries. For example, forcing function 110 shown in FIG. 1B can operate as a switchable or variable load under the control of microprocessor 118. As discussed above, when configured as a load, element 110 may be a resistor that is selectively coupled to the battery 102, may be multiple resistors providing multiple resistance levels, or may be a variable resistor or otherwise variable load. For example, FIG. 2A is a simplified schematic diagram showing forcing function/switchable load 110 configured as a load resistor 200. Load resistor 200 is selectively coupled to the terminal of the battery 102 using the Kelvin connection 106 through switch 202. Switch 202 is operated under the control of microprocessor 118. FIG. 2B shows another example configuration in which forcing function/switchable load 110 is configured as a variable resistance 204 controlled by microprocessor 118. In some configurations, a digital to analog converter may be implemented to provide such control.

During operation, the voltage source 109 shown in FIG. 1A applies a voltage across the string of batteries 102. At least some of the batteries 102 are arranged in a series connection such that the batteries are “float” charged with a constant voltage. The switchable load 110 provides a battery voltage control mechanism whereby the voltage on individual batteries 102 may be decreased with respect to the “float” average. In one specific configuration, the switchable load 110 is applied for a fixed time interval to partially discharge a targeted battery 102 through the Kelvin connections 106. This reduces the voltage of the target battery with respect to the average voltage across the individual batteries 102 in the string. Further, this causes the remaining “unloaded” batteries to have individual voltages which will increase such that the total voltage applied across the string remains the same. Low voltage batteries will thus have an incremental voltage rise while the battery voltage will decrease on the targeted battery that has been partially discharged with the switchable load 110.

The system 100 determines which battery or batteries 102 to load based upon measured parameters of the batteries 102. For example, in one configuration, voltage measurements are made during charging and/or operation of the batteries 102. If a battery is identified which has a higher voltage, the switchable load 110 may be applied as desired. The application may be periodic and continued measurements of the individual batteries may be taken during this period. Once a voltage on a particular battery reaches a particular level, application of the switchable load 110 may be stopped. The particular level may be determined based upon thresholds including fixed values as well as based upon the voltage measured with respect to other batteries 102 within the string of batteries. The voltage across a battery 102 may be monitored using differential amplifier 112. Other types of measurements may also be made to determine application of the switchable load 110. For example, current measurements may be used to measure the current flowing through a battery as well as dynamic parameter measurements may be used directly or for use in determining state of health and/or state of charge of a particular battery 102. The application of the switchable load may be controlled by individual battery monitors 130 or may be controlled by the main controller 134. Although FIG. 1B shows communication between the individual modules 130 and the main controller 134, in another example configuration communication is provided between modules 130. In such a configuration, main controller 134 may not be required.

As discussed above, the communication between modules 130 and/or main controller 134 may be a wired or wireless communication.

In another aspect, the switchable load 110 may be used to prevent a thermal runaway condition in a battery 102. In such a configuration, if a particular battery is receiving an excessive current level, the battery may be caused to overheat and thereby have its resistance reduced such that additional current is drawn. The switchable load 110 may be used as a current shunt to thereby reduce the current level applied to an individual battery 102. The determination of excessive current draw and/or thermal runaway may be detected by measuring current or voltage levels as well as detecting using a temperature sensor such as temperature sensor 210A and 210N showing in FIG. 1B.

The switchable load may be controlled based upon any appropriate technique. For example, parameters of individual batteries can be measured and the variable or controllable load can be applied based upon the measured parameters. The parameters may be static parameters such as a voltage across a battery or a current through a battery, as well as dynamic parameters such as dynamic conductance, resistance, inductance, admittance, etc. Although the configuration discussed herein uses the same forcing function to operate as a fixable load, in other example configurations these elements may be separated into two separate components. Depending upon the amount of current drawn by a switchable load, additional heat sinking or other thermal dissipation techniques may be required. The forcing function and sense amplifier provide one example of battery test circuitry which may optionally include an analog to digital converter and a microprocessor. The various charging and loading techniques may be implemented in software, for example software stored in memory 120 or 142. Diagnostic information may be provided to a user, for example through I/O 126 or display 146 shown in FIG. 1B. Such diagnostic information may include the identification of a failed or failing battery, information about loading of individual batteries, parameter measurements including static and dynamic parameters, etc. The switchable load may be applied in other manners, for example, in order to selectively reduce a charging voltage applied to a battery based upon other considerations such as a preferred charging profile for a particular battery type, environmental measurements such as temperature measurements, or some other parameter. As used herein, the term “controllable electrical load” includes a switchable load as well as a variable load. In another example configuration, a battery may be selectively discharged using a controllable load.

Although the present invention has been described with reference to preferred embodiments, workers skilled in the art will recognize that changes may be made in form and detail without departing from the spirit and scope of the invention. The above methods and capability procedures are integrated and performed in the Wireless Battery Management System in which a Base Coordinator orchestrates the methods.

1. A battery maintenance system for performing maintenance on a string of storage batteries, comprising:
a plurality of battery monitors each of which is configured to electrically couple to a battery in the string of batteries and measure parameters of batteries in the string;
a plurality of controllable electrical loads each of which are configured to electrically couple to a battery within the string of batteries; and
wherein the controllable electric load is controlled during charging of the string of batteries as a function of the measured parameters measured by the plurality of battery monitors.

2. (canceled)

3. (canceled)

4. The battery maintenance system of claim 1 wherein the measured parameters comprise voltages.

5. The battery maintenance system of claim 1 wherein the measured parameters comprise dynamic parameters.

6. The battery maintenance system of claim 5 wherein the dynamic parameters comprises dynamic conductance.

7. The battery maintenance system of claim 1 wherein the charging of the string of batteries is through application of a desired voltage to the string of batteries.

8. The battery maintenance system of claim 1 wherein the charging of the string of batteries is through application of a desired current.

9. The battery maintenance system of claim 1 wherein the plurality of battery monitors include temperature sensors configured to sense a temperatures of the batteries in the string of batteries.

10. The battery maintenance system of claim 9 wherein the measured parameter comprises temperature.

11. The battery maintenance system of claim 10 wherein the controllable electric load is controlled to prevent a thermal runaway condition.

12. The battery maintenance system of claim 1 wherein the controllable electrical load comprises a switched resistance.

13. The battery maintenance system of claim 1 wherein the controllable electrical load comprises a variable resistance.

14. The battery maintenance system of claim 1 wherein the plurality of battery monitors are configured for wireless communication.

15. The battery maintenance system of claim 1 including a central controller in communication with the plurality of monitors.

16. The battery maintenance system of claim 15 wherein the central controller controls operation of the controllable electrical load.

17. The battery maintenance system of claim 1 wherein the controllable electrical load provides a forcing function for use in measuring a dynamic parameter of the battery.

18. The battery maintenance system of claim 1 wherein the controllable electrical load is controlled based upon a battery type.

19. The battery maintenance system of claim 1 wherein the controllable electrical load is controlled to select a desired charging profile for a battery.

20. The battery maintenance system of claim 1 including a battery charger configured to charge the string of batteries.

21. A method for performing maintenance on a string of batteries, comprising:
measuring an electrical parameter of each battery in the string of batteries using a plurality of battery monitors connected to a plurality of batteries in a string of batteries;
applying a charging voltage across the string of batteries;
applying a controllable electric load to at least one of the batteries in the string of batteries based upon an output from the battery monitor.

22. The method of claim 21 wherein the measured parameters comprise voltages.

23. The method of claim 21 wherein the measured parameters comprise a dynamic parameter.

24. The method of claim 21 wherein the dynamic parameter comprises dynamic conductance.

25. The method of claim 21 including sensing temperature of the batteries in the string of batteries.

26. The method of claim 25 wherein the measured parameter comprises temperature.

27. The method of claim 21 including controlling the controllable electric load to prevent a thermal runaway condition.

28. The method of claim 21 wherein the controllable electrical load is controlled using wireless communication.

29. The method of claim 28 wherein the wireless communication is with a central controller.

30. The method of claim 21 including providing a forcing function for measuring a dynamic parameter using the controllable electrical load.

31. The method of claim 28 wherein the central controller controls operation of the controllable electrical load.

32. The method of claim 31 wherein the controllable electrical load provides a forcing function for use in measuring a dynamic parameter of the battery.

33. A battery maintenance system for maintaining a plurality of batteries connected to a battery charger comprising at least one battery monitor connected to at least one of the plurality of batteries, the battery monitor comprising:
first and second electrical connectors configured to electrical couple respective positive and negative terminals of the at least one of the plurality of batteries;
battery test circuitry coupled to the first and second electrical connectors configured to measure an electrical parameter of the at least one battery of the plurality of batteries;
a controllable electrical load coupled to the first and second configured to apply an electrical load to the at least one battery of the plurality of batteries; and
a controller coupled to the battery test circuitry and the controllable electrical load configured to control the controllable electrical load and apply the electrical load to the at least one battery of the plurality of batteries as a function of the measured electrical parameter to thereby control a charging voltage applied to the at least one battery or the plurality of batteries during charging of the plurality of batteries by the battery charger.

34. The battery maintenance system of claim 33 wherein the measured parameter comprise voltage.

35. The battery maintenance system of claim 33 wherein the measured parameter comprise a dynamic parameter.

36. The battery maintenance system of claim 33 wherein the battery monitors include a temperature sensor configured to sense a temperature of the battery.

37. The battery maintenance system of claim 33 wherein the controllable electric load is controlled to prevent a thermal runaway condition in the battery.

38. The battery maintenance system of claim 33 wherein the controllable electrical load comprises a switched resistance.

39. The battery maintenance system of claim 33 wherein the controllable electrical load comprises a variable resistance.

40. The battery maintenance system of claim 33 wherein the battery monitor is configured for wireless communication.

41. The battery maintenance system of claim 33 wherein the controllable electrical load provides a forcing function for use in measuring a dynamic parameter of the battery.

42. The battery maintenance system of claim 33 wherein the controllable electrical load is controlled based upon a battery type.

43. The battery maintenance system of claim 33 wherein the controllable electrical load is controlled to select a desired charging profile for a battery.
